(19) United States
(12) Patent Application Publication
(10) Pub. No.: US 2024/0282800 A1
(43) Pub. Date: Aug. 22, 2024

(54) IMAGE SENSOR AND METHOD OF MANUFACTURING THE SAME

(71) Applicant: Samsung Electronics Co., Ltd., Suwon-si (KR)

(72) Inventors: Takekazu Shinohara, Suwon-si (KR); Heetak Han, Suwon-si (KR); Masato Fujita, Suwon-si (KR)

(21) Appl. No.: 18/441,571

(22) Filed: Feb. 14, 2024

(30) Foreign Application Priority Data
Feb. 16, 2023 (KR) 10-2023-0020812

(51) Int. Cl. H01L 27/146; H01L 21/223; H01L 21/762; H01L 21/768

(52) U.S. Cl. CPC H01L 27/14683; H01L 21/2236; H01L 21/76224; H01L 21/76831; H01L 21/76867

(57) ABSTRACT

Provided are an image sensor and a method of manufacturing the image sensor. The method includes forming a pixel isolation trench in a semiconductor substrate to extend from a first surface of the semiconductor substrate to the inside of the semiconductor substrate, forming a sacrificial layer on an inner wall of the pixel isolation trench, implanting a p-type impurity from a surface of the sacrificial layer into the sacrificial layer and the semiconductor substrate by a plasma doping process, a first concentration of the p-type impurity at the surface of the sacrificial layer being greater than a second concentration of the p-type impurity at a sidewall of the pixel isolation trench, removing the sacrificial layer, and forming a pixel isolation structure by forming an insulating liner and a conductive layer sequentially on the inner wall of the pixel isolation trench.

### CROSS-REFERENCE TO RELATED APPLICATION

This application is based on and claims priority under 35 U.S.C. § 119 to Korean Patent Application No. 10-2023-0020812, filed on Feb. 16, 2023, in the Korean Intellectual Property Office, the disclosure of which is incorporated by reference herein in its entirety.

### BACKGROUND

The inventive concept relates to an image sensor and a method of manufacturing the image sensor, and more particularly, to an image sensor including a deep trench isolation structure.

Image sensors are devices for converting images into electrical signals. Image sensors have a plurality of pixels, and each pixel includes a photodiode region for receiving incident light to perform photoelectric conversion and charge accumulation and a pixel circuit for amplifying charges generated in the photodiode region and outputting a pixel signal. With the rising levels of image sensor integration, pixel size reduction poses a challenge in achieving both reduced dark current and adequate full well capacity.

### SUMMARY

The inventive concept provides an image sensor, which may effectively suppress dark current and improve full well capacity, and a method of manufacturing the image sensor.

According to an embodiment of the present disclosure, a method of manufacturing an image sensor includes forming a pixel isolation trench at a first surface of a semiconductor substrate, wherein the pixel isolation trench is defined by a recessed first surface of the semiconductor substrate and a side surface thereof that connects the recessed first surface to the first surface, the recessed first surface corresponds to a bottom surface of the pixel isolation trench, and the side surface of the semiconductor substrate corresponds to a side surface of the pixel isolation trench, forming a sacrificial layer on the side surface of the pixel isolation trench, doping a p-type impurity into the semiconductor substrate via an interface between the sacrificial layer and the side surface of the pixel isolation trench using a plasma doping process performed on a first surface of the sacrificial layer, wherein a first concentration of the p-type impurity at the first surface of the sacrificial layer is greater than a second concentration of the p-type impurity at the side surface of the pixel isolation trench, and the side surface of the pixel isolation trench contacts a second surface of the sacrificial layer which is opposite to the first surface thereof in a horizontal direction that is parallel to the first surface of the semiconductor substrate, removing the sacrificial layer to expose the side surface of the pixel isolation trench, and forming a pixel isolation structure by forming an insulating liner and a conductive layer sequentially on the exposed side surface of the pixel isolation trench.

According to an embodiment of the present disclosure, a method of manufacturing an image sensor includes forming a pixel isolation trench at an upper surface of a substrate to define each of a plurality of pixels, forming a sacrificial layer on a side surface of the pixel isolation trench, doping a p-type impurity into the sacrificial layer and the substrate via the pixel isolation trench using a plasma doping process, wherein the plasma doping process is performed on a surface of the sacrificial layer to generate a doping profile of the p-type impurity in which a concentration of the p-type impurity gradually decreases as a distance increases in a horizontal direction from the surface of the sacrificial layer toward the inside of the substrate, and wherein the horizontal direction is parallel to the upper surface of the substrate, removing the sacrificial layer to expose the side surface of the pixel isolation trench, and forming a pixel isolation structure by forming an insulating liner and a conductive layer sequentially on the exposed side surface of the pixel isolation trench.

According to an embodiment of the present disclosure, a method of manufacturing an image sensor includes forming a pixel isolation trench at an upper surface of a substrate to define each of a plurality of pixels, forming a sacrificial layer on a side surface of the pixel isolation trench, forming a p-type neutral region at a side surface of the substrate by doping a p-type impurity into the sacrificial layer and the substrate using a plasma doping process performed on a surface of the sacrificial layer, wherein the side surface of the substrate corresponds to the side surface of the pixel isolation trench, and the p-type neutral region contacts the side surface of the pixel isolation trench, removing the sacrificial layer to expose the side surface of the pixel isolation trench, and forming a pixel isolation structure by forming an insulating liner and a conductive layer sequentially on the exposed side surface of the pixel isolation trench, wherein an average concentration of the p-type impurity in the p-type neutral region is selected from a range of 2×10¹⁷ cm⁻³ or less.

According to an embodiment of the present disclosure, an image sensor includes a semiconductor substrate comprising a plurality of pixels and having a first surface and a second surface opposite to the first surface, each of the plurality of pixels comprising a photoelectric conversion region therein between the first and second surfaces, a pixel isolation structure arranged in a pixel isolation trench, wherein the pixel isolation trench extends from the first surface of the semiconductor substrate to the inside of the semiconductor substrate and, when viewed in a plan view, surrounds each of the plurality of pixels, and wherein the pixel isolation structure fills the pixel isolation trench and includes an insulating liner on a side surface of the pixel isolation trench and a conductive layer on the insulating liner, a p-type neutral region arranged in the semiconductor substrate and disposed between the photoelectric conversion region and the pixel isolation structure, wherein the p-type neutral region is doped with a p-type impurity at a concentration selected from a range of 2×1017 cm−3 or less, a pixel transistor on the first surface of the semiconductor substrate, and a micro-lens on the second surface of the semiconductor substrate.

### BRIEF DESCRIPTION OF THE DRAWINGS

Embodiments will be more clearly understood from the following detailed description taken in conjunction with the accompanying drawings in which:

FIG. 1 is a layout diagram illustrating an image sensor according to some embodiments;

FIG. 2 is a cross-sectional view of the image sensor, taken along line A1-A1′ of FIG. 1;

FIG. 3 schematically illustrates the concentration of a p-type impurity that is implanted into a portion of a semiconductor substrate from the point X1 up to the point X2 of FIG. 2;

FIG. 4 is an equivalent circuit diagram of a pixel according to some embodiments;

FIGS. 5 to 15 are schematic diagrams illustrating a method of manufacturing an image sensor, according to some embodiments, and in particular, FIGS. 5 to 8, 9A, and 10 to 15 are cross-sectional views of the image sensor, taken along line A1-A1′ of FIG. 1, FIG. 9B is a horizontal cross-sectional view at a first vertical level of FIG. 9A, and FIG. 9C schematically illustrates the concentration of a p-type impurity that is implanted into a portion of a semiconductor substrate with a sacrificial layer deposited on a side surface of the pixel isolation trench from the first point Y1 up to the second point Y2 of FIG. 9A;

FIGS. 16, 17A, and 17B are schematic diagrams illustrating a method of manufacturing an image sensor, according to some embodiments;

FIG. 18 is a schematic diagram illustrating simulation results to which a manufacturing method according to some embodiments is applied; and

FIG. 19 is a block diagram illustrating a configuration of an image sensor according to some embodiments.

### DETAILED DESCRIPTION OF THE EMBODIMENTS

Hereinafter, embodiments of the inventive concept will be described in detail with reference to the accompanying drawings.

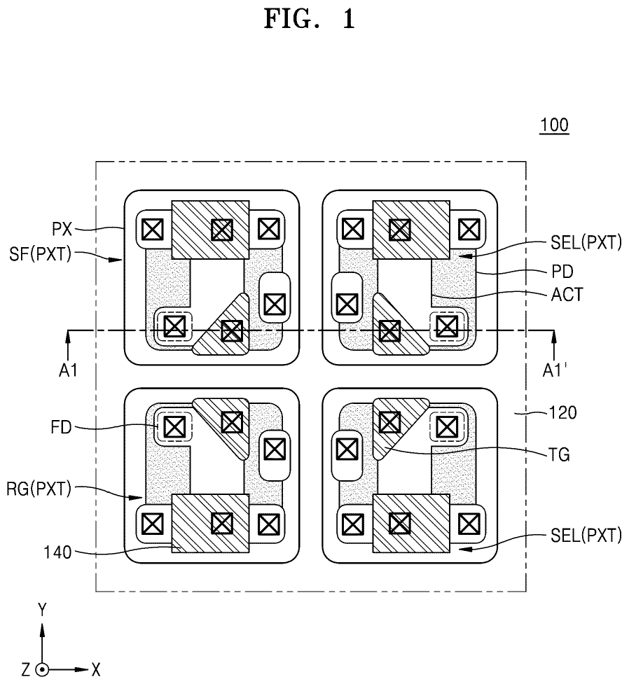

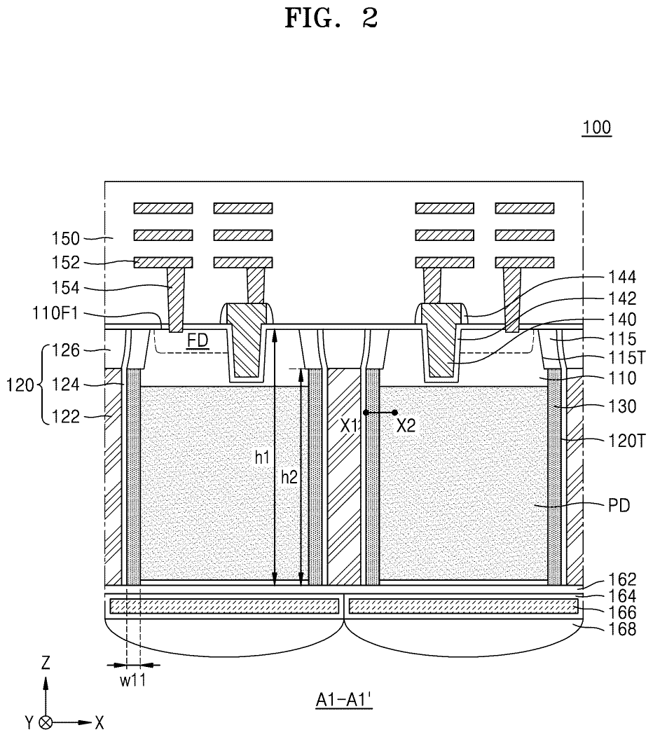

FIG. 1 is a layout diagram illustrating an image sensor 100 according to some embodiments. FIG. 2 is a cross-sectional view of the image sensor 100, taken along line A1-A1′ of FIG. 1.

Referring to FIGS. 1 and 2, the image sensor 100 may include a semiconductor substrate 110 including a plurality of pixels PX.

The semiconductor substrate 110 may include a first surface 110F1 and a second surface 110F2, which are opposite to each other. In some embodiments, the semiconductor substrate 110 may include or may be a p-type semiconductor substrate. For example, the semiconductor substrate 110 may include or may be a p-type silicon substrate. In some embodiments, the semiconductor substrate 110 may include or may be a p-type bulk substrate and a p-type or n-type epitaxial layer grown on the p-type bulk substrate. In some embodiments, the semiconductor substrate 110 may include or may be an n-type bulk substrate and a p-type or n-type epitaxial layer grown on the n-type bulk substrate.

The plurality of pixels PX may be arranged in a matrix form in the semiconductor substrate 110, and a plurality of photoelectric conversion regions PD may be respectively arranged in the plurality of pixels PX. A photoelectric conversion region PD may include a region doped with an n-type impurity. For example, the photoelectric conversion region PD may have a difference in impurity concentration between an upper portion and a lower portion thereof and thus have a potential gradient. Alternatively, the photoelectric conversion region PD may be formed in a structure in which a plurality of impurity regions are stacked in a vertical direction (Z direction). A p-well region (not shown) may be arranged in a portion of the semiconductor substrate 110, which is adjacent to the first surface 110F1 of the semiconductor substrate 110. The p-well region may be arranged adjacent to the photoelectric conversion region PD and may include a region doped with a p-type impurity. In some embodiments, the photoelectric conversion region PD may correspond to a depletion region formed at p-n junction.

A device isolation film 115 may be formed on the first surface 110F1 of the semiconductor substrate 110 to define an active region ACT. The device isolation film 115 may be arranged in a device isolation trench 115T, which is formed with a certain depth in the first surface 110F1 of the semiconductor substrate 110. The device isolation film 115 may include or may be formed of silicon oxide, silicon nitride, silicon oxynitride, or a combination thereof.

A pixel isolation structure 120 may be arranged in the semiconductor substrate 110, and the plurality of pixels PX may be defined by the pixel isolation structure 120. The pixel isolation structure 120 may be arranged between one of the plurality of photoelectric conversion regions PD and a photoelectric conversion region PD adjacent thereto. One photoelectric conversion region PD and another photoelectric conversion region PD adjacent thereto may be electrically isolated by the pixel isolation structure 120. The pixel isolation structure 120 may be arranged between the plurality of photoelectric conversion regions PD arranged in a matrix form and may have a grid or mesh shape when viewed in a plan view.

The pixel isolation structure 120 may be formed in a pixel isolation trench 120T. The pixel isolation trench 120T may passes through the semiconductor substrate 110 from the first surface 110F1 up to the second surface 110F2 of the semiconductor substrate 110. The pixel isolation structure 120 may include a conductive layer 122, an insulating liner 124, and an upper insulating layer 126.

The insulating liner 124 may be arranged on an inner wall (i.e., a side surface) of the pixel isolation trench 120T and may extend from the first surface 110F1 to the second surface 110F2 of the semiconductor substrate 110. The conductive layer 122 may be surrounded by the insulating liner 124 and may fill the inside of the pixel isolation trench 120T. The upper insulating layer 126 may be arranged in a portion of the pixel isolation trench 120T, which is adjacent to the first surface 110F1 of the semiconductor substrate 110. The upper insulating layer 126 may be arranged on an upper surface of the conductive layer 122 and may fill an entrance portion of the pixel isolation trench 120T. In some embodiments, the pixel isolation structure 120 having the insulating liner 124, the conductive layer 122, and the upper insulating layer 126 may completely fill the pixel isolation trench 120T. In some embodiments, the upper insulating layer 126 may fill the entrance portion of the pixel isolation trench 120T, and the insulating liner 124 and the conductive layer 122 may fill the remaining portion of the pixel isolation trench 120T below the entrance portion.

In some embodiments, the conductive layer 122 may include or may be formed of at least one of doped polysilicon, a metal, a metal silicide, a metal nitride, and a metal-containing film. In some embodiments, the insulating liner 124 may include or may be formed of an insulating material, such as silicon oxide, silicon nitride, and silicon oxynitride. The upper insulating layer 126 may include or may be formed of an insulating material, such as silicon oxide, silicon nitride, and silicon oxynitride.

In some embodiments, the pixel isolation structure 120 may include the insulating liner 124 filling the inside of the pixel isolation trench 120T and the conductive layer 122 may be omitted from the pixel isolation structure 120. The insulating liner 124 may include or may be formed of a metal oxide, such as hafnium oxide, aluminum oxide, and tantalum oxide. The insulating liner 124 may function as a negative fixed charge layer.

A p-type neutral region 130 (i.e., a neutral region) may be surrounded by the pixel isolation structure 120 in each pixel PX when viewed in a plan view. The p-type neutral region 130 may be a region arranged in the semiconductor substrate 110 and doped with a p-type impurity, and the p-type impurity may include boron (B). As used herein, the term “neutral region” may refer to a region, in which the sum of respective charges of carriers and impurity ions in a semiconductor is 0, and which is electrically neutral. The p-type neutral region 130 may be a region, which is doped with a p-type impurity and electrically neutral even when the photoelectric conversion region PD is depleted, and to which no electric field (E-field) is applied.

In some embodiments, the p-type neutral region 130 may have a relatively low impurity concentration, and in some embodiments, the p-type neutral region 130 may have an impurity concentration of 2×10¹⁷ cm⁻³ or less. In some embodiment, the p-type neutral region 130 may have an average impurity concentration of a range of 1×10¹⁵ cm⁻³ to 2×10¹⁷ cm⁻³. In addition, the p-type neutral region 130 may have a first width w11, which is relatively small, in the horizontal direction (X direction). For example, the first width w11 of the p-type neutral region 130 may have a value selected from a range of about 5 nm to about 200 nm. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

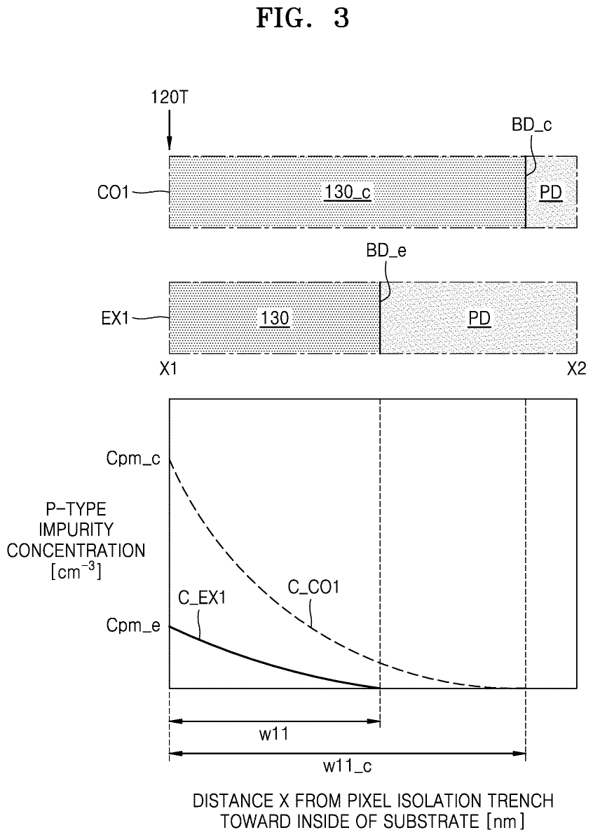

FIG. 3 schematically illustrates the concentration of a p-type impurity that is implanted into a region of the semiconductor substrate 110 which extends from the first point X1, which corresponds to a sidewall of the pixel isolation trench 120T (i.e., a side surface of the pixel isolation trench 120T) as shown in FIG. 2, up to the second point X2 inside the semiconductor substrate 110. As shown in FIG. 3, the p-type neutral region 130 may have an impurity concentration profile gradually decreasing along with the increasing horizontal-direction distance from the sidewall of the pixel isolation trench 120T toward the inside of the semiconductor substrate 110. In some embodiments, the impurity concentration of the p-type neutral region 130 may gradually decrease in the form of an exponential function along with the increasing horizontal-direction distance from the sidewall of the pixel isolation trench 120T toward the inside of the semiconductor substrate 110.

Specifically, in FIG. 3, the p-type impurity concentration of the p-type neutral region 130 in Example EX1 is indicated by a first curve C_EX1 corresponding to the solid line, and for comparison, the p-type impurity concentration of a p-type neutral region 130_c in Comparative Example CO1 is indicated by a second curve C_CO1 corresponding to the dashed line.

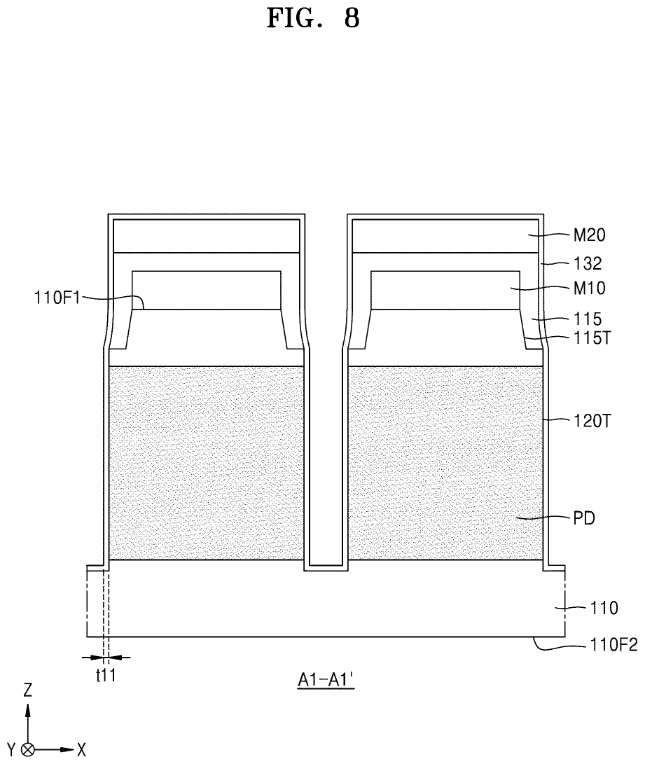

As described below, in Example EX1, the p-type neutral region 130 is formed by a plasma doping process P210 by using a sacrificial layer 132 (see FIG. 8), and in Comparative Example CO1, the p-type neutral region 130_c is formed by a general plasma doping process without using the sacrificial layer 132.

For example, according to Example EX1, the p-type neutral region 130 may have a maximum concentration Cpm_e of the p-type impurity at the sidewall of the pixel isolation trench 120T. An average concentration of the p-type impurity in the p-type neutral region 130 may be 2×10¹⁷ cm⁻³ or less. On the other hand, according to Comparative Example CO1, the p-type neutral region 130_c may have a maximum concentration Cpm_c of the p-type impurity at the sidewall of the pixel isolation trench 120T and the maximum concentration Cpm_c of the p-type impurity may be greater than the maximum concentration Cpm_e of the p-type impurity. An average concentration of the p-type impurity in the p-type neutral region 130_c may be 2×10¹⁹ cm⁻³ or more. The maximum concentration Cpm_e of the p-type impurity in Example EX1 may correspond to about 0.1% to about 10% of the maximum concentration Cpm_c of the p-type impurity in Comparative Example CO1.

In Example EX1, the p-type neutral region 130 having a relatively low impurity concentration may be obtained, and thus, a boundary BD_e between the p-type neutral region 130 and the photoelectric conversion region PD may be positioned at a distance selected from a range of about 5 nm to about 200 nm from the sidewall of the pixel isolation trench 120T. In other words, the p-type neutral region 130 may be arranged to have the first width w11, which is relatively small, and the photoelectric conversion region PD surrounded by the p-type neutral region 130 may have a larger width compared to when the p-type neutral region 130 is not formed.

On the other hand, in Comparative Example CO1, the p-type neutral region 130_c having a relatively high impurity concentration may be obtained, and thus, a boundary BD_c between the p-type neutral region 130_c and the photoelectric conversion region PD may be located apart from the sidewall of the pixel isolation trench 120T toward the inside of the semiconductor substrate 110 by as much as a significant distance. In other words, in Comparative Example CO1, the p-type neutral region 130_c may be arranged to have a width w11_c, which is relatively great, and thus, the photoelectric conversion region PD surrounded by the p-type neutral region 130_c may have a relatively small width.

Referring again to FIG. 2, in some embodiments, the p-type neutral region 130 may be arranged adjacent to the sidewall of the pixel isolation structure 120 throughout substantially the total height of the pixel isolation structure 120. For example, an upper surface of the p-type neutral region 130 may be in contact with a lower surface of the device isolation film 115 and may be at a vertical level that is equal to or similar to that of an upper surface of the conductive layer 122 (for example, a first end of the conductive layer 122, which is close to the first surface 110F1 of the semiconductor substrate 110). In some embodiments, the pixel isolation structure 120 may have a first height h1 in the vertical direction (Z direction), the p-type neutral region 130 may have a second height h2 in the vertical direction (Z direction), and the second height h2 of the p-type neutral region 130 may be less than the first height h1 of the pixel isolation structure 120. The term “contact,” as used herein, refers to a direct connection (i.e., physical touching) unless the context indicates otherwise.

Transistors constituting a pixel circuit PXT may be arranged on the active region ACT. For example, the active region ACT may be a portion of the semiconductor substrate 110, on which a transmission gate TG, a source follower gate SF, a select gate SEL, and a reset gate RG are arranged. In a portion of the active region ACT, for example, a portion of the active region ACT, which is adjacent to the transmission gate TG, a floating diffusion region FD may be arranged.

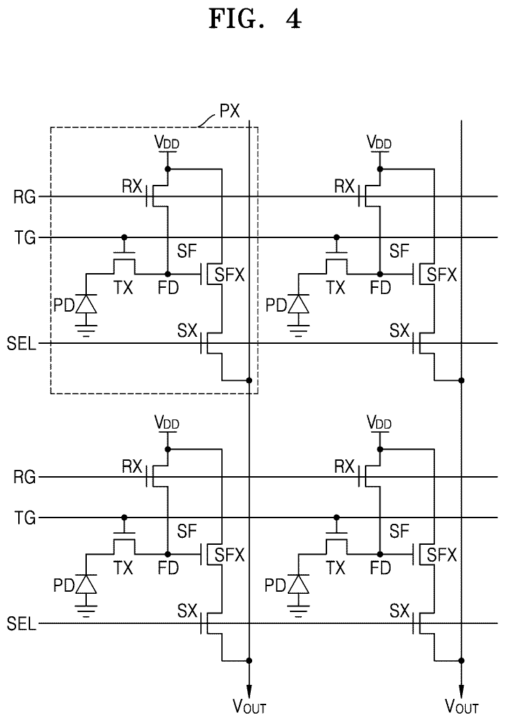

In some embodiments, the transmission gate TG may constitute a transmission transistor TX (see FIG. 4) and the transmission transistor TX may be configured to transmit charges generated in the photoelectric conversion region PD to the floating diffusion region FD. The reset gate RG may constitute a reset transistor RX (see FIG. 4), and the reset transistor RX may be configured to cyclically reset charges stored in the floating diffusion region FD. The source follower gate SF may constitute a source follower transistor SFX (see FIG. 4), and the source follower transistor SFX may function as a source follower amplifier and be configured to buffer a signal according to the charges stored in the floating diffusion region FD. The select gate SEL may constitute a select transistor SX (see FIG. 4), and the select transistor SX may perform switching and addressing for selecting a pixel PX.

Each of the transmission gate TG, the reset gate RG, the source follower gate SF, and the select gate SEL may include a gate electrode 140. For example, the gate electrode 140 may be arranged in a buried gate trench 140T or on the first surface 110F1 of the semiconductor substrate 110.

In some embodiments, the gate electrode 140 may include or may be formed of at least one of doped polysilicon, a metal, a metal silicide, a metal nitride, and a metal-containing film. A gate insulating layer 142 may be arranged between the gate electrode 140 and the first surface 110F1 of the semiconductor substrate 110 and on an inner wall of the buried gate trench 140T. A gate spacer 144 may be arranged on a sidewall of the gate electrode 140.

The floating diffusion region FD may be arranged in the semiconductor substrate 110 on one side of the gate electrode 140. In some embodiments, the floating diffusion region FD may include or may be a region doped with a first impurity and, for example, the first impurity may include an n-type impurity. In some embodiments, the first impurity may include phosphorus or arsenic.

An interlayer dielectric 150 may be arranged on the first surface 110F1 of the semiconductor substrate 110. The interlayer dielectric 150 may cover the active region ACT, the device isolation film 115, and the gate electrode 140. In some embodiments, the interlayer dielectric 150 may include or may be formed of silicon nitride or silicon oxynitride.

A contact 154 may be electrically connected with the semiconductor substrate 110 or the gate electrode 140 and may be surrounded by the interlayer dielectric 150. In addition, a wiring layer 152 may be arranged to be electrically connected with the contact 154. For example, each of the wiring layer 152 and the contact 154 may include or may be formed of at least one of impurity-doped or undoped polysilicon, a metal, a metal silicide, a metal nitride, and a metal-containing film. In some embodiments, each of the wiring layer 152 and the contact 154 may include or may be formed of tungsten, aluminum, copper, tungsten silicide, titanium silicide, tungsten nitride, titanium nitride, doped polysilicon, or the like.

A backside insulating layer 162 may be arranged on the second surface 110F2 of the semiconductor substrate 110. In some embodiments, the backside insulating layer 162 may include or may be formed of a metal oxide, such as hafnium oxide, aluminum oxide, and tantalum oxide. In some embodiments, the backside insulating layer 162 may include or may be formed of an insulating material, such as silicon oxide, silicon nitride, silicon oxynitride, and a low-k dielectric insulating material.

A passivation layer 164 may be arranged on the backside insulating layer 162, and a color filter 166 and a micro-lens 168 may be arranged on the passivation layer 164.

In general, to prevent the dark current of an image sensor, a negative bias is applied to a pixel isolation structure and a p-type neutral region including a p-type impurity is formed around the pixel isolation structure. However, when a general plasma doping process is used, a photoelectric conversion region has a relatively small volume in a pixel due to the significantly high doping concentration of the p-type impurity, and thus, there is an issue of the deterioration in dynamic range (DNR) or signal-to-noise ratio (SNR) due to the reduction of a full well capacity. In some embodiments, a sensor with a larger full well capacity may have larger DNR or SNR.

In an image sensor according to some embodiments, the p-type neutral region 130 may be formed by doping a p-type impurity from the inner wall of the pixel isolation trench 120T into the semiconductor substrate 110 through a plasma doping process by using the sacrificial layer 132 (see FIG. 8). Because the p-type impurity has a concentration profile gradually decreasing from a surface of the sacrificial layer 132 to the inside of the semiconductor substrate 110, the p-type neutral region 130 may have a relatively low impurity concentration and the photoelectric conversion region PD may have a relatively great volume in a pixel. The image sensor 100 may allow dark current to be effectively suppressed by holes accumulated by the p-type neutral region 130 and the pixel isolation structure 120 and may have an improved full well capacity by allowing the photoelectric conversion region PD to secure a great volume.

FIG. 4 is an equivalent circuit diagram of a pixel PX according to some embodiments.

Referring to FIG. 4, a plurality of pixels PX may be arranged in a matrix form. Each of the plurality of pixels PX may include a transmission transistor TX and logic transistors. Here, the logic transistors may include a reset transistor RX, a select transistor SX, and a source follower transistor SFX. The reset transistor RX may include a reset gate RG, the select transistor SX may include a select gate SEL, the source follower transistor SFX may include a source follower gate SF, and the transmission transistor TX may include a transmission gate TG.

Each of the plurality of pixels PX may further include a photoelectric conversion region PD and a floating diffusion region FD. The photoelectric conversion region PD may generate and accumulate photocharges in proportion to the amount of light incident from outside the pixel PX, and the photoelectric conversion region PD may include a photodiode, a phototransistor, a photogate, a pinned photodiode (PPD), or a combination thereof.

The transmission gate TG may transmit charges generated in the photoelectric conversion region PD to the floating diffusion region FD. The floating diffusion region FD may receive the charges generated in the photoelectric conversion region PD and convert the charges into a voltage that depends on the quantity of charge. The source follower gate SF of the source follower transistor SFX may be connected to the floating diffusion region FD, and the source follower transistor SFX may be controlled according to the voltage of the floating diffusion region FD.

The reset transistor RX may cyclically reset the charges accumulated in the floating diffusion region FD. A drain electrode of the reset transistor RX is connected with floating diffusion region FD, and a source electrode of the reset transistor RX is connected with a power supply voltage VDD. When the reset transistor RX is turned on, the power supply voltage VDD connected with the source electrode of the reset transistor RX is transferred to the floating diffusion region FD. When the reset transistor RX is turned on, the charges accumulated in the floating diffusion region FD may be discharged, and thus, the floating diffusion region FD may be reset.

The source follower transistor SFX is connected with a current source (not shown) located outside a matrix of the plurality of pixels PX to function as a source follower amplifier, amplify a change in potential in the floating diffusion region FD, and output the change in potential to an output line V_{OUT}.

The select transistor SX may select a plurality of pixels PX on a row basis, and an output voltage generated by the source follower transistor SFX when the select transistor SX is turned on may be transferred to the output line V_{OUT}.

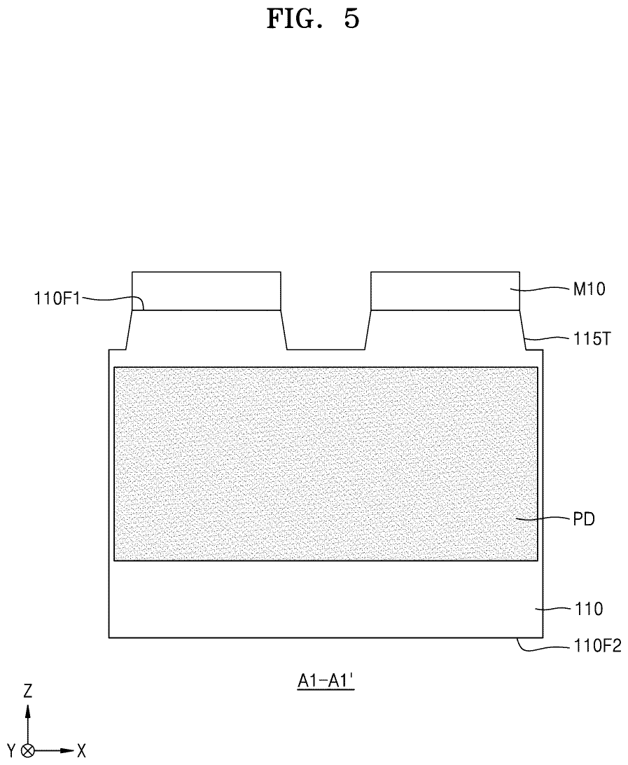

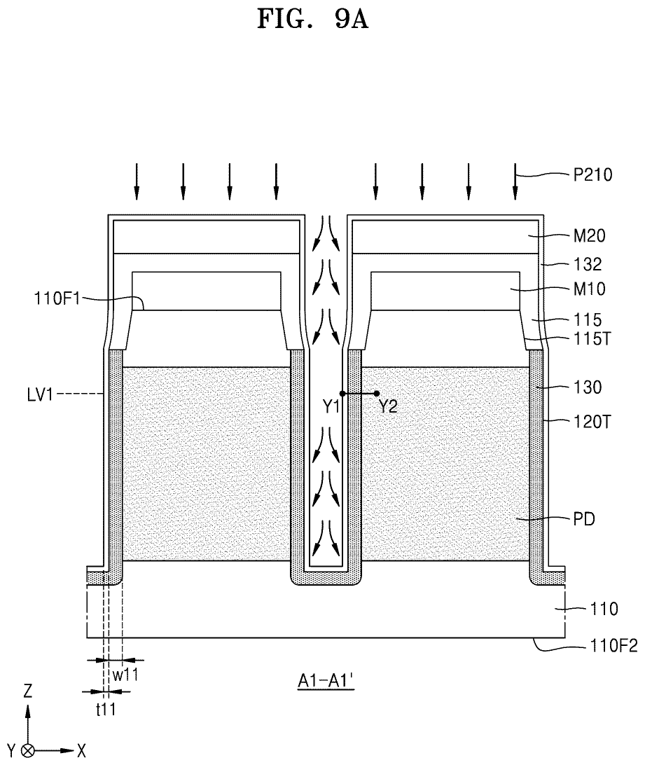

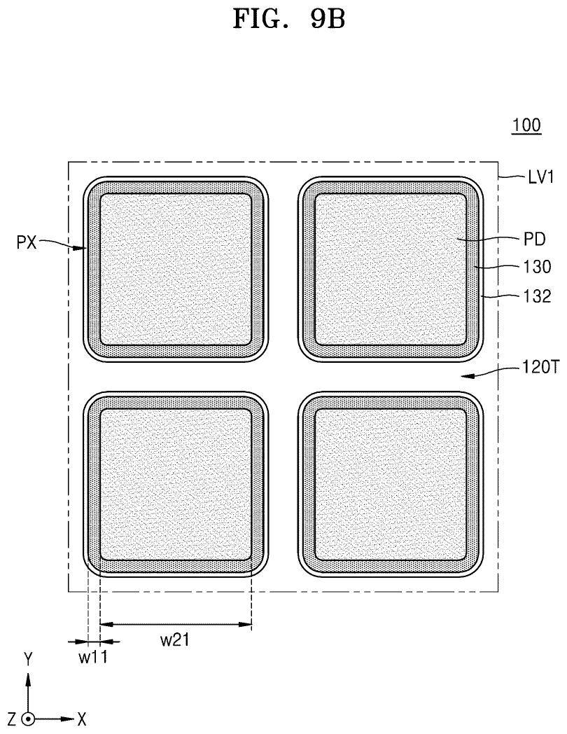

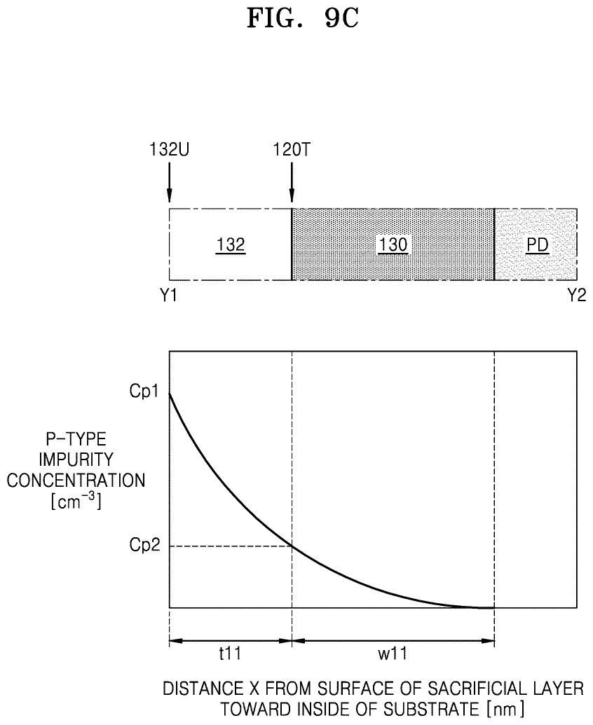

FIGS. 5 to 15 are schematic diagrams illustrating a method of manufacturing an image sensor, according to some embodiments. Specifically, FIGS. 5 to 8, 9A, and 10 to 15 are cross-sectional views of the image sensor, taken along line A1-A1′ of FIG. 1, FIG. 9B is a horizontal cross-sectional view at a first vertical level of FIG. 9A, and FIG. 9C schematically illustrates the concentration of a p-type impurity that is implanted into a portion of a semiconductor substrate 110 with a sacrificial layer deposited on a side surface of the pixel isolation trench 120T from a first point Y1 up to a second point Y2 of FIG. 9A.

Referring to FIG. 5, the semiconductor substrate 110 having the first surface 110F1 and the second surface 110F2, which are opposite to each other, is prepared.

In some embodiments, the semiconductor substrate 110 may include or may be a p-type semiconductor substrate. For example, the semiconductor substrate 110 may include or may be a p-type silicon substrate. In some embodiments, the semiconductor substrate 110 may include or may be a p-type bulk substrate and a p-type or n-type epitaxial layer grown thereon. In some embodiments, the semiconductor substrate 110 may include or may be an n-type bulk substrate and a p-type or n-type epitaxial layer grown thereon.

The photoelectric conversion region PD may be formed by an ion implantation process that is performed on the first surface 110F1 of the semiconductor substrate 110. In some embodiments, the ion implantation process may include a doping process by diffusion. In some embodiments, the photoelectric conversion region PD may be formed by doping the semiconductor substrate 110 with an n-type impurity. For example, the photoelectric conversion region PD may have a difference in impurity concentration between an upper portion and a lower portion thereof and thus have a potential gradient along the vertical direction. Alternatively, the photoelectric conversion region PD may be formed in a structure in which a plurality of impurity regions are vertically stacked.

Next, a first mask pattern M10 may be formed on the first surface 110F1 of the semiconductor substrate 110, and the device isolation trench 115T may be formed in the semiconductor substrate 110 by using the first mask pattern M10 as an etch mask.

In some embodiments, the device isolation trench 115T may be formed to have a height of about 100 nm to about 500 nm in the vertical direction (Z direction) that is perpendicular to the first surface 110F1 of the semiconductor substrate 110, but the inventive concept is not limited thereto.

FIG. 5 illustrates an example of a cross-sectional shape of the device isolation trench 115T of the planar layout shown in FIG. 1, and the planar shape or the cross-sectional shape of the device isolation trench 115T may vary depending on the number and layout of pixel circuits PXT (see FIG. 1) to be subsequently arranged on the first surface 110F1 of the semiconductor substrate 110.

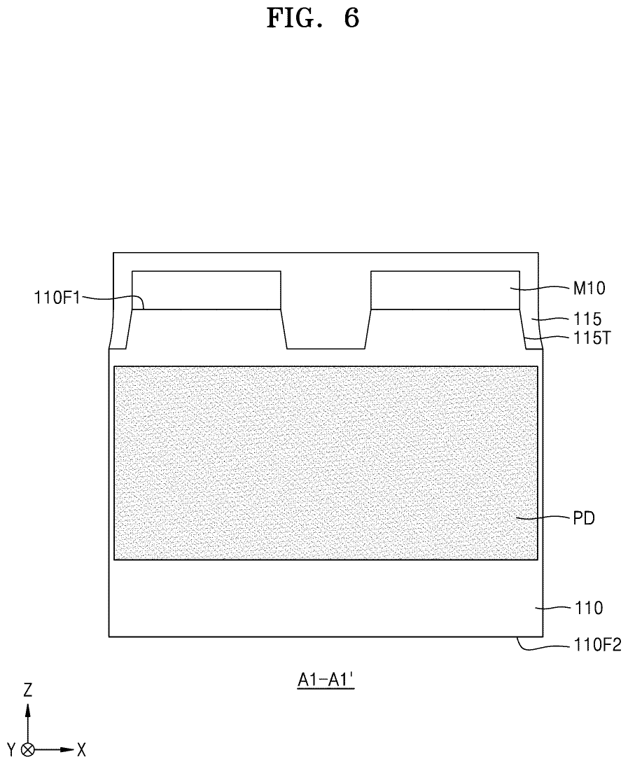

Referring to FIG. 6, the device isolation film 115 may be formed on the first mask pattern M10 to fill the inside of the device isolation trench 115T and may cover the first mask pattern M10. In some embodiments, the device isolation film 115 may include or may be formed of an insulating material.

In some embodiments, the device isolation film 115 may include or may be formed of at least one of silicon oxide, silicon nitride, and silicon oxynitride.

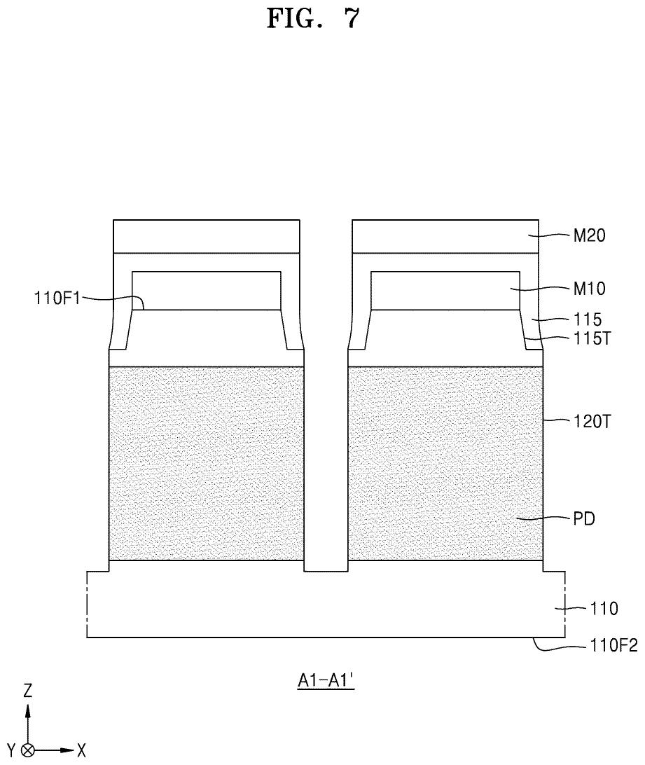

Referring to FIG. 7, a second mask pattern M20 may be formed on an upper surface of the device isolation film 115, and the pixel isolation trench 120T may be formed in the semiconductor substrate 110 by using the second mask pattern M20 as an etch mask. The pixel isolation trench 120T may have a certain depth from the first surface 110F1 of the semiconductor substrate 110 and may be formed in a matrix form when viewed in a plan view. In some embodiments, the pixel isolation trench 120T may extend from a bottom surface of the device isolation trench 115T toward the second surface 110F2 of the semiconductor substrate 110. In some embodiments, the pixel isolation trench 120T may extend from an upper surface of the semiconductor substrate 110 toward the second surface 110F2. A bottom surface of the pixel isolation trench 120T may correspond to a recessed upper surface of the semiconductor substrate 110 which is formed by an etching process using the second mask pattern M20 as an etch mask. A side surface of the pixel isolation trench 120T may correspond to a side surface of the semiconductor substrate 110 which is exposed by the formation of the pixel isolation trench 120T. The side surface of the semiconductor substrate 110 may connect the recessed upper surface of the semiconductor substrate 110 to the upper surface thereof. In some embodiments, the first surface 110F1 of the semiconductor substrate 110 may include an upper surface connecting two adjacent device isolation trenches 115T, a side surface of the device isolation trench 115T, and a bottom surface of the device isolation trench 115T.

Referring to FIG. 8, the sacrificial layer 132 may be formed on an inner wall of the pixel isolation trench 120T. In some embodiments, the sacrificial layer 132 may be formed by a thermal oxidation process, a chemical vapor deposition (CVD) process, an atomic layer deposition (ALD) process, or the like. For example, the sacrificial layer 132 may include or may be formed of at least one of silicon oxide, silicon nitride, borophosphosilicate glass (BPSG), and borosilicate glass (BSG).

In some embodiments, the sacrificial layer 132 may be conformally formed on the inner wall of the pixel isolation trench 120T to cover an upper surface of the second mask pattern M20 and a sidewall of the device isolation film 115. The sacrificial layer 132 may be formed with a thickness not to completely fill the inside of the pixel isolation trench 120T, and in some embodiments, the sacrificial layer 132 may be formed with a first thickness t11 selected from a range of about 2 nm to about 20 nm.

For example, the sacrificial layer 132 may be formed using a deposition process, such as a chemical vapor deposition, having an excellent step coverage, and the first thickness t11 of the sacrificial layer 132 may be relatively uniform throughout the total height of the pixel isolation trench 120T in the vertical direction (Z direction). For example, when the thickness of the sacrificial layer 132 is measured at a plurality of positions in the vertical direction (Z direction) along the pixel isolation trench 120T, the ratio of the minimum thickness of the sacrificial layer 132 to the maximum thickness of the sacrificial layer 132 may have a value selected from a range of about 80% to about 100%.

Referring to FIGS. 9A to 9C, a p-type impurity may be implanted into a portion of a semiconductor substrate 110 with a sacrificial layer 132 deposited on the sidewall of the pixel isolation trench 120T by performing the plasma doping process P210 on a surface 132U of the sacrificial layer 132, thereby forming the p-type neutral region 130.

In some embodiments, the plasma doping process P210 may include a doping process using plasma including p-type impurity ions. For example, the p-type impurity ions may include boron (B) ions. For example, the plasma doping process P210 may include a process via which an exposed surface is doped with impurity ions at a dose of 2×10¹⁵ cm⁻².

The p-type impurity may be implanted into the semiconductor substrate 110 from the surface 132U of the sacrificial layer 132, which is exposed at the sidewall of the pixel isolation trench 120T, by the plasma doping process P210, and the p-type impurity may be implanted from the sidewall of the pixel isolation trench 120T into a portion of the semiconductor substrate 110. Here, the portion of the semiconductor substrate 110, into which the p-type impurity is implanted, may be referred to as the p-type neutral region 130.

FIG. 9B illustrates a horizontal cross-sectional view at the first vertical level LV1 of FIG. 9A, and FIG. 9C schematically illustrates the concentration of the p-type impurity that is implanted into a semiconductor substrate 110 with a sacrificial layer 132 from the first point Y1 at the surface 132U of the sacrificial layer 132 up to the second point Y2 inside the semiconductor substrate 110, as shown in FIG. 9A. As shown in FIG. 9C, the p-type impurity may have a concentration profile, in which the concentration of the p-type impurity gradually decreases along with the increasing horizontal-direction distance x from the first point Y1 at the surface 132U of the sacrificial layer 132 toward the inside of the semiconductor substrate 110. In some embodiments, the concentration of the p-type may gradually decrease in the form of an exponential function along with the increasing horizontal-direction distance x from the first point Y1 at the surface 132U of the sacrificial layer 132 toward the inside of the semiconductor substrate 110.

In some embodiments, the surface 132U of the sacrificial layer 132 may have a first concentration Cp1 of the p-type impurity, the sidewall of the pixel isolation trench 120T may have a second concentration Cp2 of the p-type impurity, and the second concentration Cp2 may be less than the first concentration Cp1. In some embodiments, the first concentration Cp1 of the p-type impurity at the surface 132U of the sacrificial layer 132 may be 2×10¹⁹ cm⁻³ or more and the second concentration Cp2 of the p-type impurity at the sidewall of the pixel isolation trench 120T may be 2×10¹⁷ cm⁻³ or less. In some embodiments, the ratio of the first concentration Cp1 to the second concentration Cp2 may be about 10 to about 1000.

In some embodiments, the second concentration Cp2 of the p-type impurity at the sidewall of the pixel isolation trench 120T may be 2×10¹⁷ cm⁻³ or less and the concentration of the p-type impurity in the p-type neutral region 130 may be less than the second concentration Cp2 and may gradually decrease in the horizontal direction, that is, a direction toward the inside of the semiconductor substrate 110.

In some embodiments, the p-type neutral region 130 may be formed with the first width w11 in the horizontal direction and the first width w11 of the p-type neutral region 130 may have a value selected from a range of about 5 nm to about 200 nm. As the p-type impurity is implanted from the sidewall of the pixel isolation trench 120T by the plasma doping process P210, a sidewall of the photoelectric conversion region PD may be moved toward the inside of the semiconductor substrate 110 and may be spaced apart from the side surface of the pixel isolation trench 120T. In some embodiments, the photoelectric conversion region PD may be surrounded by the p-type neutral region 130 when viewed in a plan view. In some embodiments, a portion of the photoelectric conversion region PD, which is adjacent to the sidewall of the pixel isolation trench 120T, may be converted into the p-type neutral region 130 by the p-type impurity that is diffused from the pixel isolation trench 120T in the plasma doping process P210.

The p-type neutral region 130 may have a relatively low impurity concentration (that is, an impurity concentration that is lower than the second concentration Cp2 on average), and thus, the p-type neutral region 130 may be formed with the first width w11 that is relatively small. Therefore, in one pixel of the semiconductor substrate 110, the photoelectric conversion region PD may have a width w21 and a volume (i.e., may have a full well capacity) which is sufficient to suppress the deterioration of the DNR or SNR.

In some embodiments, the concentration of the p-type impurity may have a profile in which the concentration of the p-type impurity gradually decreases along with the increasing horizontal distance from the surface 132U of the sacrificial layer 132 toward the semiconductor substrate 110, and thus, the ratio of the first concentration Cp1 to the second concentration Cp2 may vary due to the first thickness t11 of the sacrificial layer 132. For example, as the first thickness t11 of the sacrificial layer 132 increases, the second concentration Cp2 may have a relatively smaller value, and thus, the average impurity concentration of the p-type neutral region 130 may decrease.

Although not shown, a portion of the device isolation film 115, which is in contact with the sacrificial layer 132, may also be doped with the p-type impurity, for example, boron (B) atoms, in a certain amount.

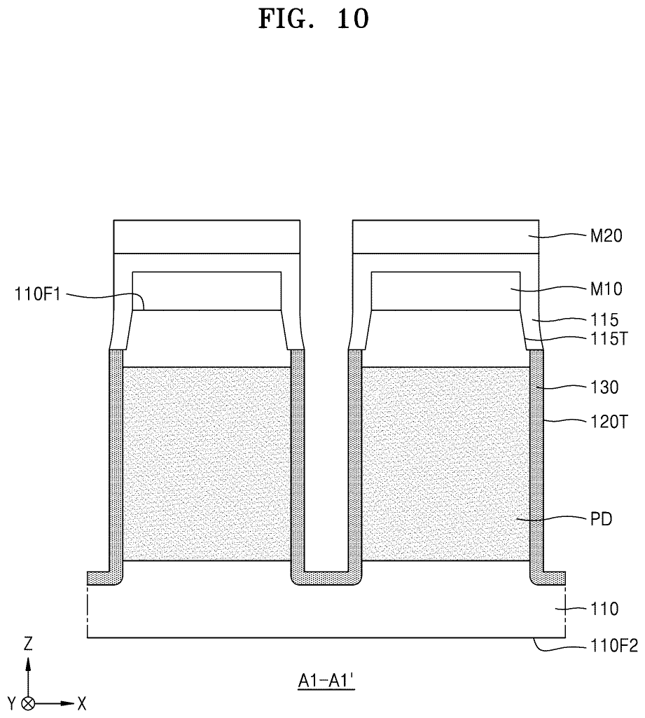

Referring to FIG. 10, the sacrificial layer 132 may be removed. In some embodiments, the sacrificial layer 132 may be removed by a wet etching process and both a portion of the sacrificial layer 132, which is arranged on the sidewall and bottom of the pixel isolation trench 120T, and a portion of the sacrificial layer 132, which is arranged on the second mask pattern M20, may be removed. As the portion of the sacrificial layer 132, which is arranged on the sidewall and bottom of the pixel isolation trench 120T, is removed, the sidewall of the p-type neutral region 130 may be exposed at the inner wall of the pixel isolation trench 120T.

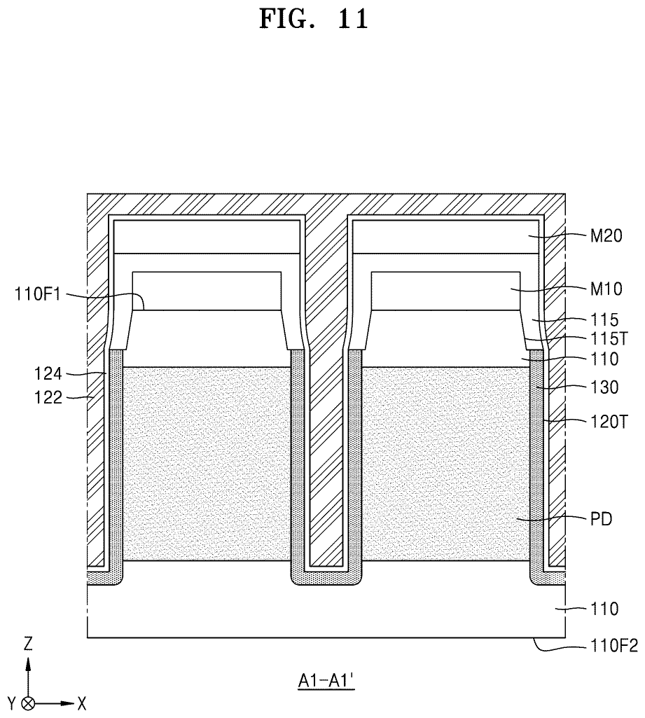

Referring to FIG. 11, the insulating liner 124 may be formed on the second mask pattern M20 and the inner wall of the pixel isolation trench 120T, and the conductive layer 122 may be formed on the insulating liner 124 to fill the inside of the pixel isolation trench 120T.

In some embodiments, the insulating liner 124 may be formed by a CVD process or an ALD process. In some embodiments, the insulating liner 124 may include or may be formed of at least one of silicon oxide, silicon nitride, and a high-k dielectric insulating material, and the conductive layer 122 may include or may be formed of at least one of doped polysilicon, a metal, a metal silicide, a metal nitride, and a metal-containing film.

For example, as the sacrificial layer 132 is removed from the inner wall of the pixel isolation trench 120T and the insulating liner 124 is formed on the inner wall of the pixel isolation trench 120T, the insulating liner 124 may not include the p-type impurity therein. In some embodiments, a separate heat treatment may not be performed between the plasma doping and the removing of the sacrificial layer 132. In some embodiments, the plasma doping may be immediately followed by the removing of the sacrificial layer 132. In some embodiments, the plasma doping may be immediately followed by the removing of the sacrificial layer 132 without an intervening process carried out at a high temperature at which may drive the p-type impurity to diffuse according to a concentration gradient thereof.

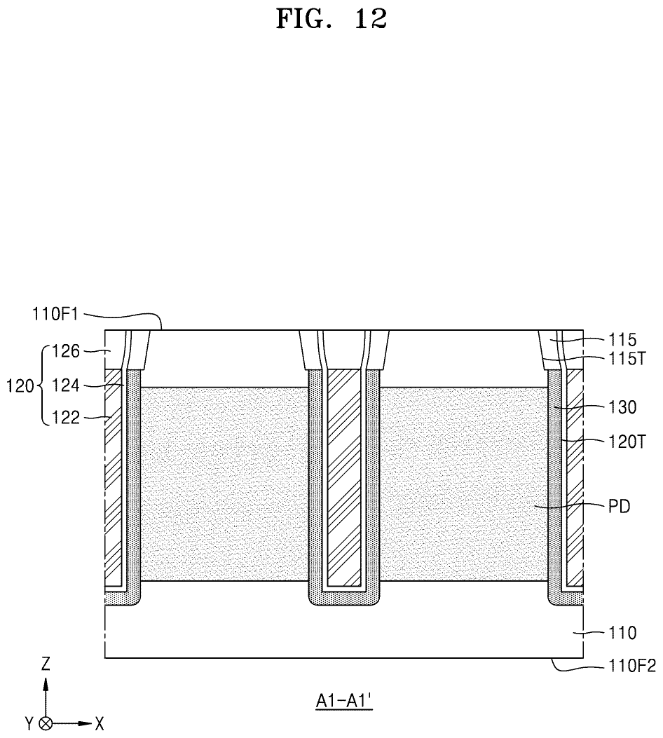

Referring to FIG. 12, an entrance portion of the pixel isolation trench 120T may be exposed by removing an upper portion of the conductive layer 122 through a recess process or an etch-back process, and then, an insulating layer (not shown) may be formed to fill the entrance portion of the pixel isolation trench 120T. Next, an upper portion of the insulating layer, a portion of the device isolation film 115, the second mask pattern M20, and the first mask pattern M10 may be removed, followed by performing a planarization process to expose the first surface 110F1 of the semiconductor substrate 110, thereby leaving the upper insulating layer 126 in the entrance portion of the pixel isolation trench 120T. Here, the conductive layer 122, the insulating liner 124, and the upper insulating layer 126 in the pixel isolation trench 120T may be collectively referred to as the pixel isolation structure 120.

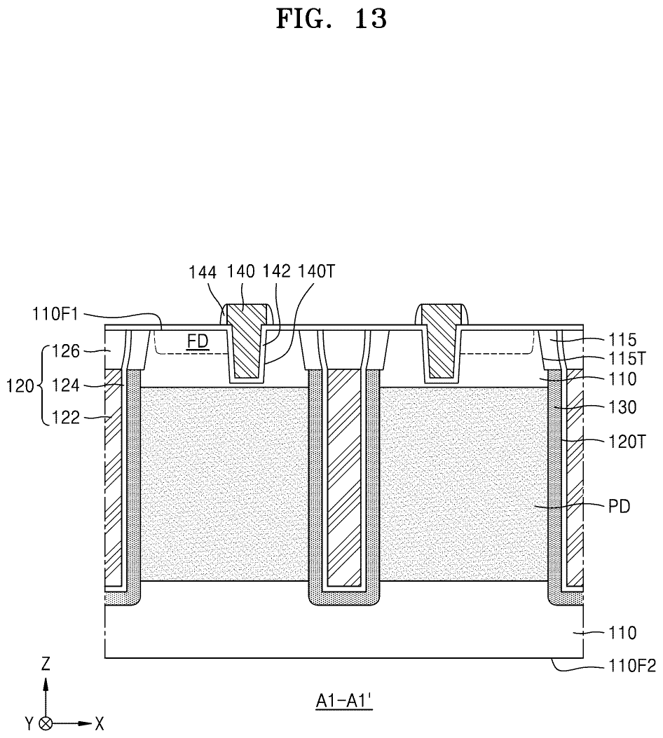

Referring to FIG. 13, a mask pattern (not shown) may be formed on the first surface 110F1 of the semiconductor substrate 110, followed by removing a portion of the semiconductor substrate 110 by using the mask pattern as an etch mask, thereby forming the buried gate trench 140T.

Next, the gate insulating layer 142 may be conformally formed on the first surface 110F1 of the semiconductor substrate 110 and an inner wall of the buried gate trench 140T. A conductive layer (not shown) may be formed on the gate insulating layer 142 and then patterned, thereby forming the gate electrode 140 on the first surface 110F1 of the semiconductor substrate 110. A portion of the gate electrode 140 may be arranged in the buried gate trench 140T, and the other portion of the gate electrode 140 may be arranged on the first surface 110F1 of the semiconductor substrate 110. In some embodiments, the gate electrode 140 may be formed of at least one of doped polysilicon, a metal, a metal silicide, a metal nitride, and a metal-containing film.

Next, the gate spacer 144 may be formed on a sidewall of the gate electrode 140. In some embodiments, an insulating layer (not shown) may be formed to cover the gate electrode 140, followed by performing anisotropic etching on the insulating layer, thereby forming the gate spacer 144 on each sidewall of the gate electrode 140.

Next, the floating diffusion region FD may be formed by performing an ion implantation process on a portion of the first surface 110F1 of the semiconductor substrate 110.

In some embodiments, the floating diffusion region FD may be formed by implanting a first impurity into the semiconductor substrate 110 from the first surface 110F1 of the semiconductor substrate 110 through the ion implantation process. For example, the first impurity may include an n-type impurity including phosphorus, arsenic, or a combination thereof.

In some embodiments, the ion implantation process may be performed before the pixel isolation structure 120 is formed. For example, after the sacrificial layer 132 is removed from the inner wall of the pixel isolation trench 120T, and before the insulating liner 124 and the conductive layer 122 are formed in the pixel isolation trench 120T, the photoelectric conversion region PD may be formed by performing the ion implantation process on the first surface 110F1 of the semiconductor substrate 110.

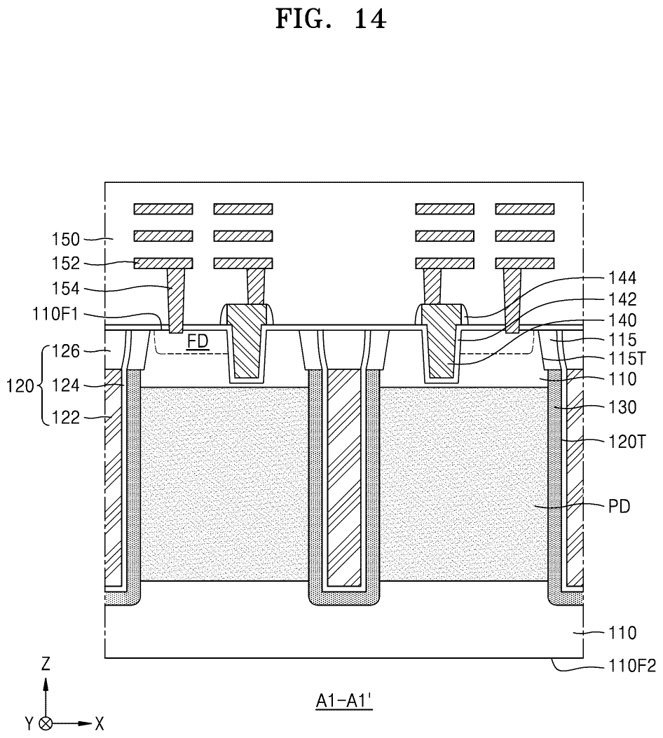

Referring to FIG. 14, the contact 154, the wiring layer 152, and the interlayer dielectric 150 may be formed on the first surface 110F1 of the semiconductor substrate 110. For example, the contact 154 may be electrically connected with an upper surface of the gate electrode 140 and an upper surface of the floating diffusion region FD.

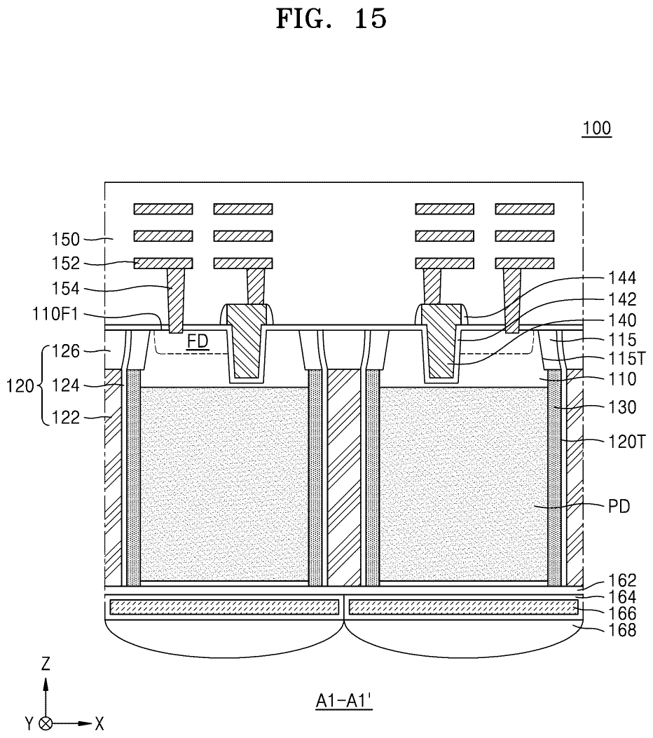

Referring to FIG. 15, a support substrate (not shown) may be bonded onto the first surface 110F1 of the semiconductor substrate 110, and the semiconductor substrate 110 may be flipped such that the second surface 110F2 of the semiconductor substrate 110 faces upward.

Next, a portion of the semiconductor substrate 110 may be removed from the second surface 110F2 of the semiconductor substrate 110 by a CMP process or an etch-back process such that an upper surface of the pixel isolation structure 120 (for example, an end of the pixel isolation structure 120, which is adjacent to the second surface 110F2 of the semiconductor substrate 110) is exposed. As the removal process set forth above is performed, a level of the second surface 110F2 of the semiconductor substrate 110 may be lowered.

Next, the backside insulating layer 162 may be formed on the second surface 110F2 of the semiconductor substrate 110. The backside insulating layer 162 may be formed on the entire area of the second surface 110F2 of the semiconductor substrate 110 to cover the pixel isolation structure 120.

Next, the passivation layer 164 may be formed on the backside insulating layer 162, and the color filter 166 and the micro-lens 168 may be formed on the passivation layer 164.

The image sensor 100 may be completely formed by the processes described above.

According to the embodiments described above, the p-type neutral region 130 may be formed by forming the sacrificial layer 132 and then implanting the p-type impurity into the pixel isolation trench 120T by the plasma doping process P210. The p-type neutral region 130 may have a relatively low doping concentration, and thus, the photoelectric conversion region PD may secure a relatively great volume in a pixel. Therefore, the image sensor 100 may efficiently remove or control dark current and may have improved DNR or SNR, and an improved full well capacity.

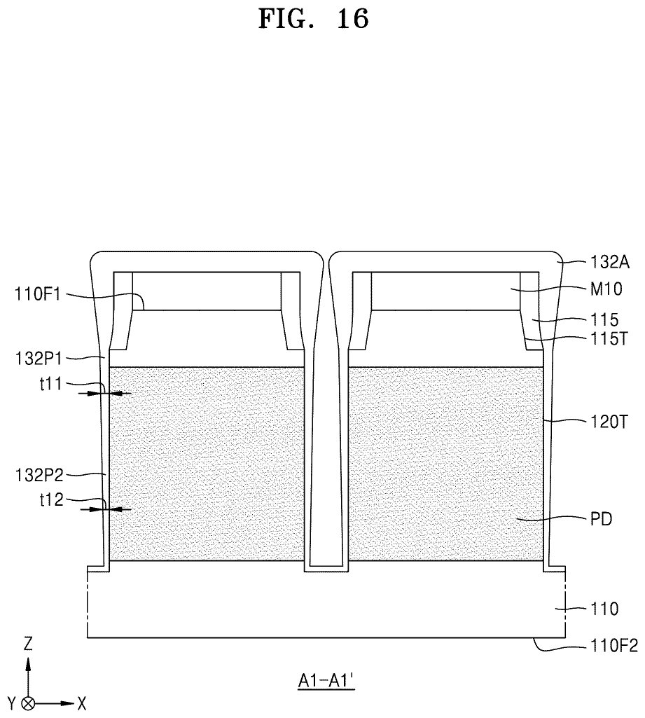

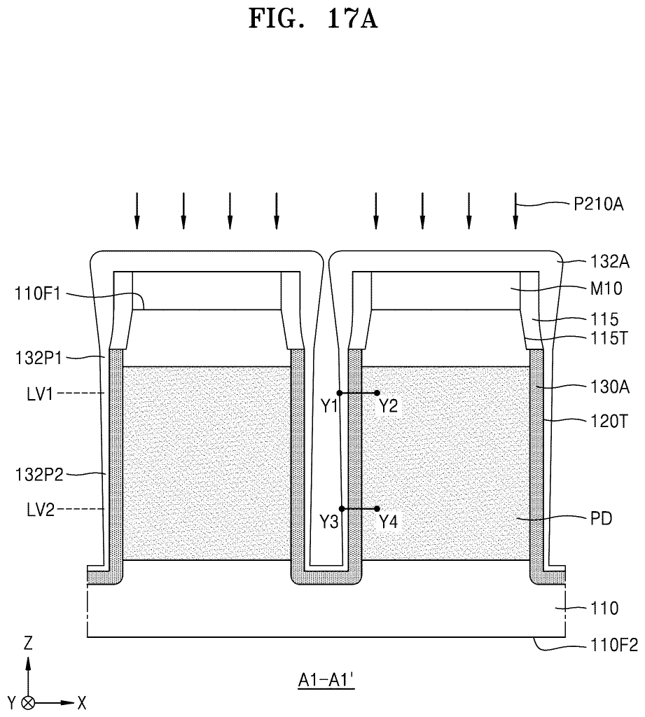

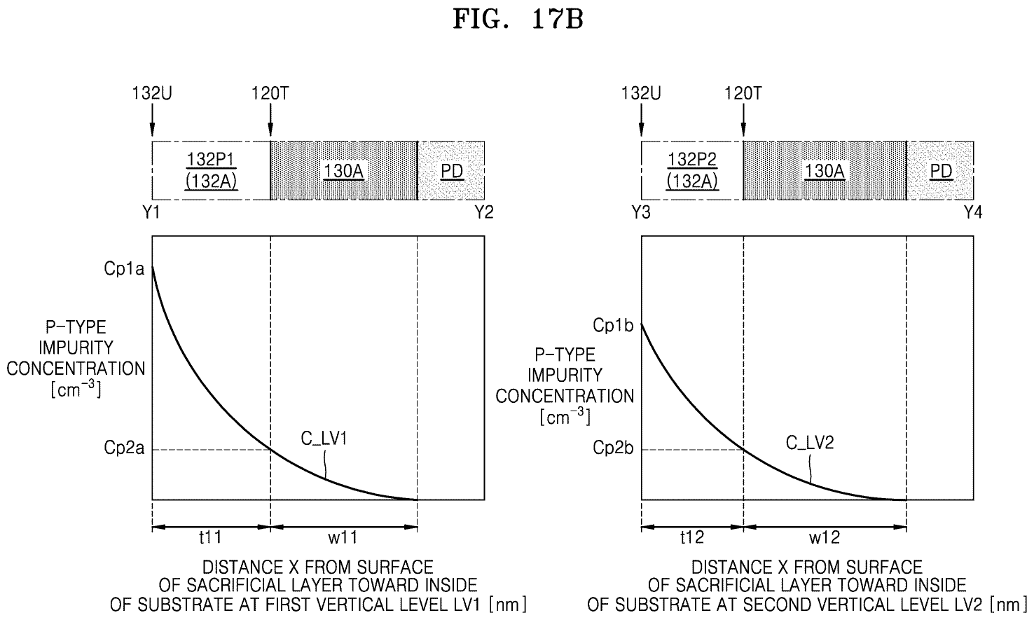

FIGS. 16, 17A, and 17B are schematic diagrams illustrating a method of manufacturing an image sensor, according to some embodiments.

Referring to FIG. 16, a sacrificial layer 132A may be formed on the inner wall of the pixel isolation trench 120T, and here, the sacrificial layer 132A may be formed by a process, such as a sputtering process, providing step coverage that is not excellent. The sacrificial layer 132A may include a first portion 132P1, which is close to the top of the pixel isolation trench 120T, and a second portion 132P2, which is close to the bottom of the pixel isolation trench 120T, and a first thickness t11 of the first portion 132P1 may be greater than a second thickness t12 of the second portion 132P2. For example, the first thickness t11 may be about 120% to about 500% of the second thickness t12.

FIG. 16 illustrates an example, in which the sacrificial layer 132A covers the respective upper surfaces of the device isolation film 115 and the first mask pattern M10, and in which the second mask pattern M20 (see FIG. 8) is removed. However, in some embodiments, unlike the example shown in FIG. 16, the second mask pattern M20 may not be removed and the sacrificial layer 132A may be formed to cover the upper surface of the second mask pattern M20.

Referring to FIGS. 17A and 17B, a p-type impurity may be implanted into the semiconductor substrate 110 from the surface 132U of the sacrificial layer 132A by performing a plasma doping process P210A, thereby forming a p-type neutral region 130A in a portion of the semiconductor substrate 110, which is adjacent to the sidewall of the pixel isolation trench 120T.

In some embodiments, the plasma doping process P210A may have nonconformal doping characteristics. For example, in the plasma doping process P210A, an impurity may be be implanted into an upper portion of a semiconductor substrate 110 with a sacrificial layer 132 deposited on a side surface of the pixel isolation trench 120T adjacent to the top of the pixel isolation trench 120T at a relatively high dose, and may be implanted into a lower portion of the semiconductor substrate with the sacrificial layer 132 deposited on the side surface of the pixel isolation trench 120T adjacent to the bottom of the pixel isolation trench 120T at a relatively low dose.

In FIG. 17B, the concentration of the p-type impurity from the first point Y1 up to the second point Y2 at a first vertical level LV1 is indicated by a first curve C_LV1 corresponding to the solid line, and the concentration of the p-type impurity from the third point Y3 up to the fourth point Y4 at a second vertical level LV2 is indicated by a second curve C_LV2 corresponding to the solid line.

As shown in FIG. 17B, when the plasma doping process P210A has nonconformal doping characteristics, a first concentration Cp1a of the p-type impurity, which is implanted into the surface 132U of the sacrificial layer 132A at the first vertical level LV1 adjacent to the top of the pixel isolation trench 120T by the plasma doping process P210A, may be greater than a third concentration Cp1b of the p-type impurity, which is implanted into the surface 132U of the sacrificial layer 132A at the second vertical level LV2 adjacent to the bottom of the pixel isolation trench 120T by the plasma doping process P210A. In some embodiments, the first concentration Cp1a may be about 120% to about 300% of the third concentration Cp1b.

As the sacrificial layer 132A has a first thickness t11 at the first vertical level LV1 adjacent to the top of the pixel isolation trench 120T and has a second thickness t12, which is less than the first thickness t11, at the second vertical level LV2 adjacent to the bottom of the pixel isolation trench 120T, a second concentration Cp2a of the p-type impurity, which is implanted into the sidewall of the pixel isolation trench 120T at the first vertical level LV1, may be similar to or approximately equal to a fourth concentration Cp2b of the p-type impurity, which is implanted into the sidewall of the pixel isolation trench 120T at the second vertical level LV2. For example, the second concentration Cp2a may be about 80% to about 120% of the fourth concentration Cp2b.

In addition, because the second concentration Cp2a of the p-type impurity, which is implanted into the sidewall of the pixel isolation trench 120T at the first vertical level LV1, is similar to or approximately equal to the fourth concentration Cp2b of the p-type impurity, which is implanted into the sidewall of the pixel isolation trench 120T at the second vertical level LV2, a width w11 of the p-type neutral region 130A at the first vertical level LV1 may be similar to or approximately equal to a width w12 of the p-type neutral region 130A at the second vertical level LV2 and, for example, the width w11 of the p-type neutral region 130A at the first vertical level LV1 may be about 80% to about 120% of the width w12 of the p-type neutral region 130A at the second vertical level LV2.

Next, the image sensor 100 may be completely formed by performing the processes described with reference to FIGS. 10 to 15.

According to some embodiments, even when the plasma doping process P210A has nonconformal doping characteristics, the impurity concentration of the p-type neutral region 130A may be adaptively adjusted by adjusting the thickness of the sacrificial layer 132A. In the embodiments shown in FIGS. 17A and 17B, the p-type neutral region 130A, which has a uniform width and/or a uniform impurity concentration throughout the total height of the pixel isolation trench 120T, may be obtained.

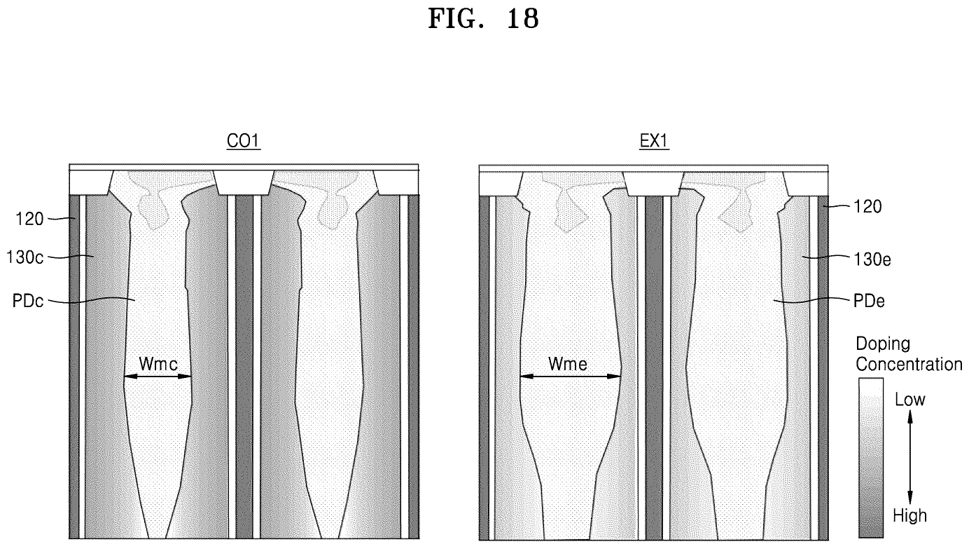

FIG. 18 is a schematic diagram illustrating simulation results to which a manufacturing method according to some embodiments is applied.

Referring to FIG. 18, respective impurity doping concentrations of a photoelectric conversion region PDc and a p-type neutral region 130c of an image sensor according to Comparative Example CO1 and respective impurity doping concentrations of a photoelectric conversion region PDe and a p-type neutral region 130e of an image sensor according to Example EX1 are illustrated.

As shown in FIG. 18, it can be confirmed that the impurity doping concentration of the p-type neutral region 130e in Example EX1 gradually decreases from a surface of the p-type neutral region 130e, which is adjacent to the pixel isolation structure 120, toward the inside of a substrate. In addition, it can be confirmed that the impurity doping concentration of the p-type neutral region 130c in Comparative Example CO1 gradually decreases from a surface of the p-type neutral region 130c, which is adjacent to the pixel isolation structure 120, toward the inside of a substrate and the maximum doping concentration of the p-type neutral region 130c in Comparative Example CO1 is higher than the maximum doping concentration of the p-type neutral region 130e in Example EX1.

Therefore, it can be confirmed that the maximum width Wmc of the photoelectric conversion region PDc surrounded by the p-type neutral region 130c in Comparative Example CO1 is less than the maximum width Wme of the photoelectric conversion region Pde surrounded by the p-type neutral region 130e in Example EX1. That is, it can be confirmed that the image sensor formed by a manufacturing method according to some embodiments may include the p-type neutral region 130e having a relatively low impurity concentration, and thus, the photoelectric conversion region Pde may secure a width or volume (i.e., may secure a full well capacity) which is sufficient to suppress dark current and the image sensor may have an improvement in DNR or SNR.

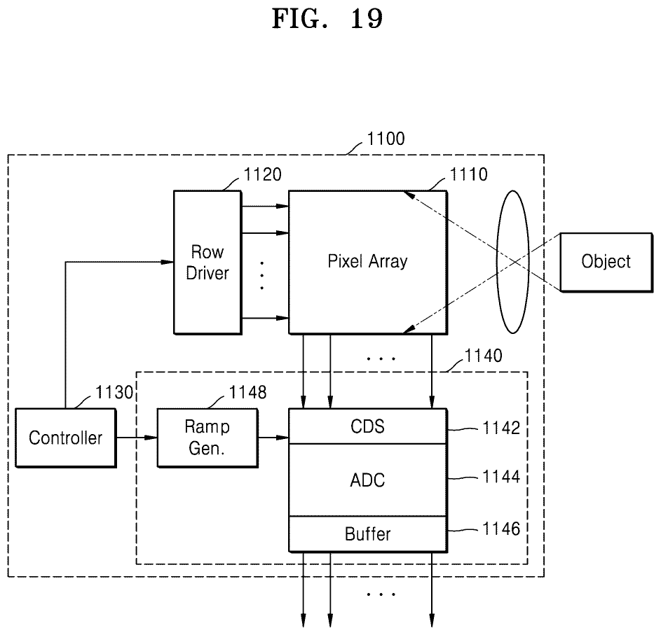

FIG. 19 is a block diagram illustrating a configuration of an image sensor 1100 according to some embodiments.

Referring to FIG. 19, the image sensor 1100 may include a pixel array 1110, a controller 1130, a row driver 1120, and a pixel signal processing unit 1140. The image sensor 1100 includes the image sensor 100 described above.

The pixel array 1110 may include a plurality of unit pixels that are 2-dimensionally arranged. A photoelectric conversion device may generate charges by absorbing light, and an electrical signal (output voltage) according to the generated charges may be provided to the pixel signal processing unit 1140 through a vertical signal line. The unit pixels of the pixel array 1110 may provide one output voltage at a time on a row basis, and thus, unit pixels belonging to one row of the pixel array 1110 may be simultaneously activated by a selection signal that is output by the row driver 1120. Unit pixels of a selected row may provide an output voltage according to absorbed light to an output line of a column corresponding thereto.

The controller 1130 may control the pixel array 1110 to absorb light and accumulate charges or to temporarily store the accumulated charges and may control the row driver 1120 to output an electrical signal according to the stored charges to the outside of the pixel array 1110. In addition, the controller 1130 may control the pixel signal processing unit 1140 to measure the output voltage provided by the pixel array 1110.

The pixel signal processing unit 1140 may include a correlated double sampler (CDS) 1142, an analog-to-digital converter (ADC) 1144, and a buffer 1146. The CDS 1142 may sample and hold the output voltage provided by the pixel array 1110. The CDS 1142 may double-sample a specific noise level and a level according to the generated output voltage and thus output a level corresponding to a difference therebetween. In addition, the CDS 1142 may receive ramp signals generated by a ramp signal generator 1148 and compare the ramp signals with each other to output a result of the comparison.

The ADC 1144 may convert an analog signal, which corresponds to the level received from the CDS 1142, into a digital signal. The buffer 1146 may latch digital signals, and the latched signals may be sequentially output to the outside of the image sensor 1100 and thus be transferred to an image processor (not shown).

While the inventive concept has been particularly shown and described with reference to embodiments thereof, it will be understood that various changes in form and details may be made therein without departing from the spirit and scope of the following claims.

1. A method of manufacturing an image sensor, the method comprising:
forming a pixel isolation trench at a first surface of a semiconductor substrate, wherein the pixel isolation trench is defined by a recessed first surface of the semiconductor substrate and a side surface thereof that connects the recessed first surface to the first surface, the recessed first surface corresponds to a bottom surface of the pixel isolation trench, and the side surface of the semiconductor substrate corresponds to a side surface of the pixel isolation trench;
forming a sacrificial layer on the side surface of the pixel isolation trench;
doping a p-type impurity into the semiconductor substrate via an interface between the sacrificial layer and the side surface of the pixel isolation trench using a plasma doping process performed on a first surface of the sacrificial layer, wherein a first concentration of the p-type impurity at the first surface of the sacrificial layer is greater than a second concentration of the p-type impurity at the side surface of the pixel isolation trench, and the side surface of the pixel isolation trench contacts a second surface of the sacrificial layer which is opposite to the first surface thereof in a horizontal direction that is parallel to the first surface of the semiconductor substrate;
removing the sacrificial layer to expose the side surface of the pixel isolation trench; and
forming a pixel isolation structure by forming an insulating liner and a conductive layer sequentially on the exposed side surface of the pixel isolation trench.

2. The method of claim 1,
wherein the sacrificial layer comprises at least one of silicon oxide, silicon nitride, borophosphosilicate glass (BPSG), and borosilicate glass (BSG).

3. The method of claim 1,
wherein a ratio of the first concentration to the second concentration of the p-type impurity is a value selected from a range of about 10 to about 1000.

4. The method of claim 1,
wherein the first concentration of the p-type impurity is an average concentration of the p-type impurity,
wherein the second concentration of the p-type impurity is an average concentration of the p-type impurity,
wherein the first concentration of the p-type impurity is a concentration selected from a range of 2×10¹⁹ cm⁻³ or more, and
wherein the second concentration of the p-type impurity is a concentration selected from a range of 2×10¹⁷ cm⁻³ or less.

5. The method of claim 1,
wherein the forming of the sacrificial layer is performed by a thermal oxidation process, a chemical vapor deposition (CVD) process, or an atomic layer deposition (ALD) process.

6. The method of claim 1,
wherein the sacrificial layer has a thickness selected from a range of about 2 nm to about 20 nm.

7. The method of claim 1,
wherein the plasma doping process is performed using a plasma comprising boron ions,
wherein the doping of the p-type impurity includes forming a p-type neutral region in the semiconductor substrate,
wherein the p-type neutral region is doped with the boron ions, and
wherein the p-type neutral region has a width selected from a range of about 5 nm to about 200 nm in the horizontal direction.

8. The method of claim 1,
wherein the plasma doping process generates a doping profile of the p-type impurity in which a concentration of the p-type impurity gradually decreases as a distance increases in the horizontal direction from the first surface of the sacrificial layer toward the inside of the semiconductor substrate.

9. The method of claim 1,
wherein the removing of the sacrificial layer is performed by a wet etching process to expose the side surface of the pixel isolation trench.

10. The method of claim 1,
wherein the doping of the p-type impurity is followed by the removing of the sacrificial layer having the first concentration of the p-type impurity at the first surface of the sacrificial layer.

11. The method of claim 1,
wherein the sacrificial layer comprises:
a first portion located close to the first surface of the semiconductor substrate and having a first width; and
a second portion located close to the bottom surface of the pixel isolation trench and having a second width that is less than the first width of the first portion, and
wherein the doping of the p-type impurity generates a doping profile of the p-type impurity in which a concentration of the p-type impurity at a surface of the first portion of the sacrificial layer is greater than a concentration of the p-type impurity at a surface of the second portion of the sacrificial layer, and
wherein a concentration of the p-type impurity in a first portion of the semiconductor substrate, which is adjacent to the surface of the first portion of the sacrificial layer, is about 80% to about 120% of a concentration of the p-type impurity in a second portion of the semiconductor substrate, which is adjacent to the surface of the second portion of the sacrificial layer.

12. A method of manufacturing an image sensor, the method comprising:
forming a pixel isolation trench at an upper surface of a substrate to define each of a plurality of pixels;
forming a sacrificial layer on a side surface of the pixel isolation trench;
doping a p-type impurity into the sacrificial layer and the substrate via the pixel isolation trench using a plasma doping process, wherein the plasma doping process is performed on a surface of the sacrificial layer to generate a doping profile of the p-type impurity in which a concentration of the p-type impurity gradually decreases as a distance increases in a horizontal direction from the surface of the sacrificial layer toward the inside of the substrate, and wherein the horizontal direction is parallel to the upper surface of the substrate;
removing the sacrificial layer to expose the side surface of the pixel isolation trench; and
forming a pixel isolation structure by forming an insulating liner and a conductive layer sequentially on the exposed side surface of the pixel isolation trench.

13. The method of claim 12,
wherein a first concentration of the p-type impurity at the surface of the sacrificial layer is greater than a second concentration of the p-type impurity at a side surface of the substrate, and
wherein the side surface of the substrate corresponds to the side surface of the pixel isolation trench.

14. The method of claim 13,
wherein the first concentration of the p-type impurity is a concentration selected from a range of 2×10¹⁹ cm⁻³ or more, and
wherein the second concentration of the p-type impurity is a concentration selected from a range of 2×10¹⁷ cm⁻³ or less.

15. The method of claim 13,
wherein a ratio of the first concentration to the second concentration of the p-type impurity is selected from a range of 10 or more.

16. The method of claim 12,
wherein the forming of the sacrificial layer is performed by a thermal oxidation process, a chemical vapor deposition (CVD) process, or an atomic layer deposition (ALD) process,
wherein the sacrificial layer comprises at least one of silicon oxide, silicon nitride, borophosphosilicate glass (BPSG), and borosilicate glass (BSG), and
wherein the sacrificial layer has a thickness selected from a range of about 2 nm to about 20 nm.

17. A method of manufacturing an image sensor, the method comprising:
forming a pixel isolation trench at an upper surface of a substrate to define each of a plurality of pixels;
forming a sacrificial layer on a side surface of the pixel isolation trench;
forming a p-type neutral region at a side surface of the substrate by doping a p-type impurity into the sacrificial layer and the substrate using a plasma doping process performed on a surface of the sacrificial layer, wherein the side surface of the substrate corresponds to the side surface of the pixel isolation trench, and the p-type neutral region contacts the side surface of the pixel isolation trench;
removing the sacrificial layer to expose the side surface of the pixel isolation trench; and
forming a pixel isolation structure by forming an insulating liner and a conductive layer sequentially on the exposed side surface of the pixel isolation trench,
wherein an average concentration of the p-type impurity in the p-type neutral region is selected from a range of 2×10¹⁷ cm⁻³ or less.

18. The method of claim 17,
wherein the forming of the p-type neutral region generates a doping profile of the p-type impurity in which a concentration of the p-type impurity gradually decreases as a distance increases in a horizontal direction from the surface of the sacrificial layer toward the inside of the substrate.

19. The method of claim 18,
wherein the insulating liner of the pixel isolation structure contacts the exposed side surface of the p-type neutral region, and
wherein the insulating liner is disposed between the conductive layer of the pixel isolation structure and the p-type neutral region.

20. The method of claim 19,
wherein the forming of the p-type neutral region generates a doping profile of the p-type impurity in which a concentration of the p-type impurity at the surface of the sacrificial layer is greater than a concentration of the p-type impurity in the p-type neutral region.

21-27. (canceled)
